(19) United States
(12) Patent Application Publication
(10) Pub. No.: US 2023/0290638 A1
(43) Pub. Date: Sep. 14, 2023

(54) SEMICONDUCTOR DEVICE STRUCTURE WITH GLUE LAYER AND METHOD FOR FORMING THE SAME

(71) Applicant: Taiwan Semiconductor Manufacturing Company, Ltd., Hsinchu (TW)

(72) Inventors: Chia-Wei CHEN, Hsinchu City (TW); Chih-Yu HSU, Xinfeng Township (TW); Cheng-Hong YANG, Hsinchu City (TW); Jian-Hao CHEN, Hsinchu City (TW); Kuo-Feng YU, Zhudong Township (TW)

(73) Assignee: Taiwan Semiconductor Manufacturing Company, Ltd., Hsinchu (TW)

(21) Appl. No.: 17/691,359

(22) Filed: Mar. 10, 2022

(51) Int. Cl. H01L 21/28; H01L 29/49; H01L 29/78; H01L 29/66

(52) U.S. Cl. CPC H01L 21/28088; H01L 29/4966; H01L 29/7851; H01L 29/66795; H01L 29/66545

(57) ABSTRACT

A method for forming a semiconductor device structure is provided. The method includes forming a gate dielectric layer over a substrate. The method includes forming a work function metal layer over the gate dielectric layer. The method includes forming a glue layer over the work function metal layer. The glue layer is thinner than the gate dielectric layer. The method includes forming a gate electrode over the glue layer. The gate electrode includes fluorine. The method includes annealing the gate electrode. The fluorine diffuses from the gate electrode into the gate dielectric layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1E are cross-sectional views of various stages of a process for forming a semiconductor device structure, in accordance with some embodiments.

FIG. 1A-1 is a top view of the semiconductor device structure of FIG. 1A, in accordance with some embodiments.

FIG. 1A-2 is a perspective view of the semiconductor device structure of FIG. 1A, in accordance with some embodiments.

FIG. 1D-1 is a top view of the semiconductor device structure of FIG. 1D, in accordance with some embodiments.

FIG. 1E-1 is a top view of the semiconductor device structure of FIG. 1E, in accordance with some embodiments.

FIG. 1E-2 is a perspective view of the semiconductor device structure of FIG. 1E, in accordance with some embodiments.

FIGS. 2A-2D are perspective views of various stages of a process for forming a semiconductor device structure, in accordance with some embodiments.

FIGS. 3A-3G are cross-sectional views of various stages of a process for forming a semiconductor device structure, in accordance with some embodiments.

FIGS. 4A-4H are cross-sectional views of various stages of a process for forming a semiconductor device structure, in accordance with some embodiments.

FIGS. 5A-5G are cross-sectional views of various stages of a process for forming a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure form a semiconductor device structure with FinFETs. The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

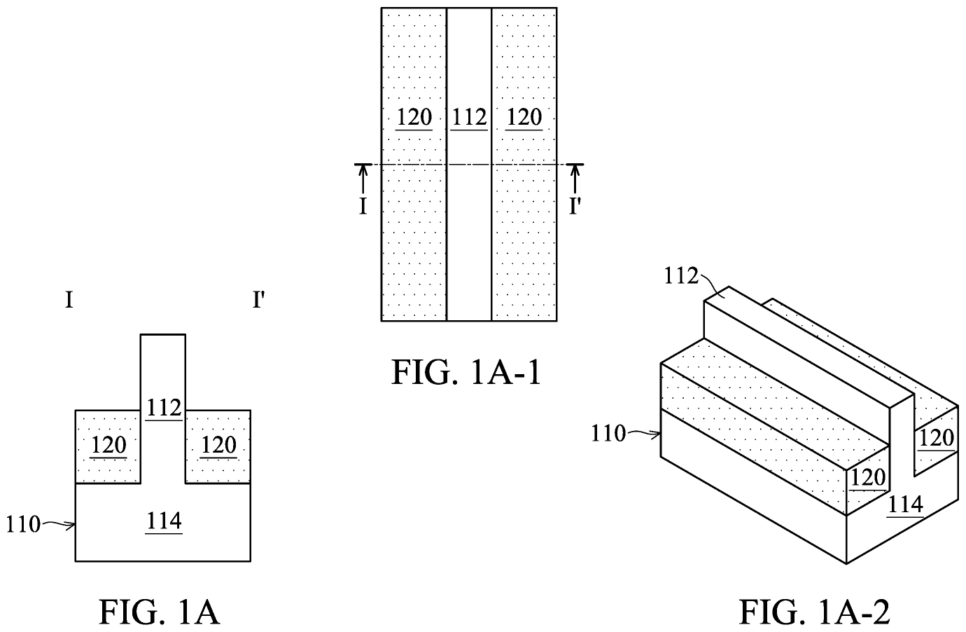

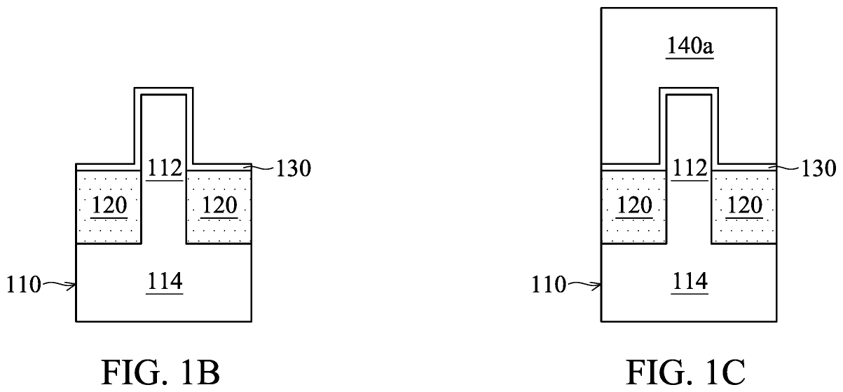

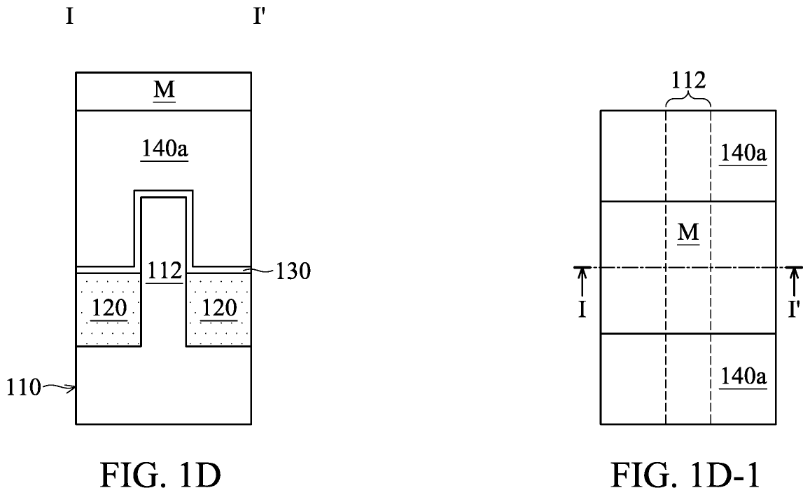

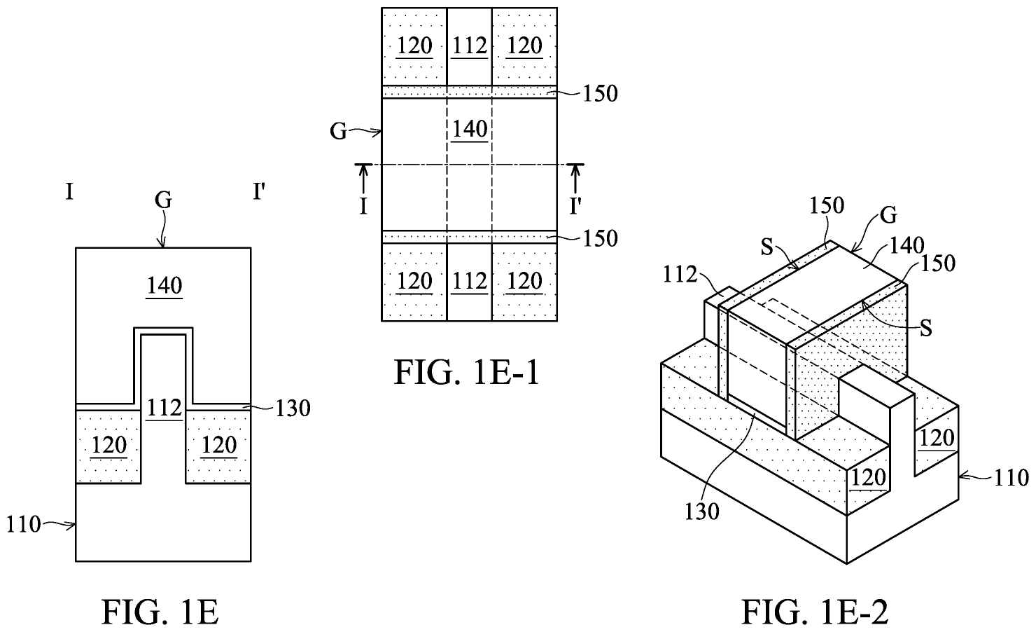

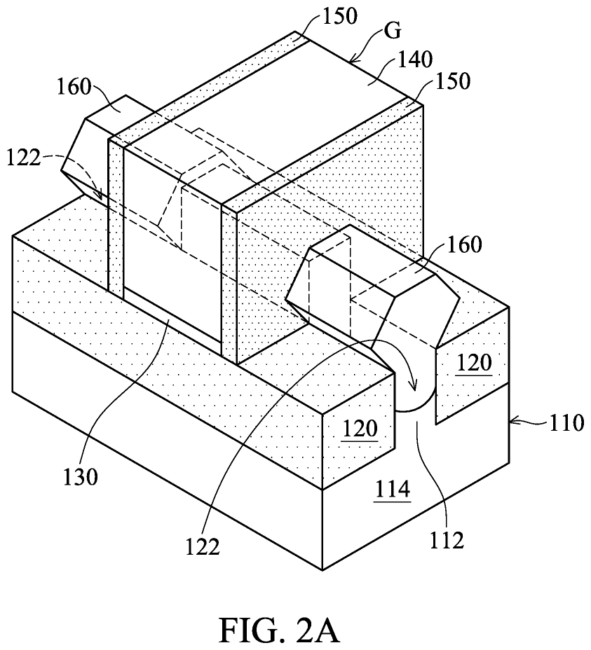

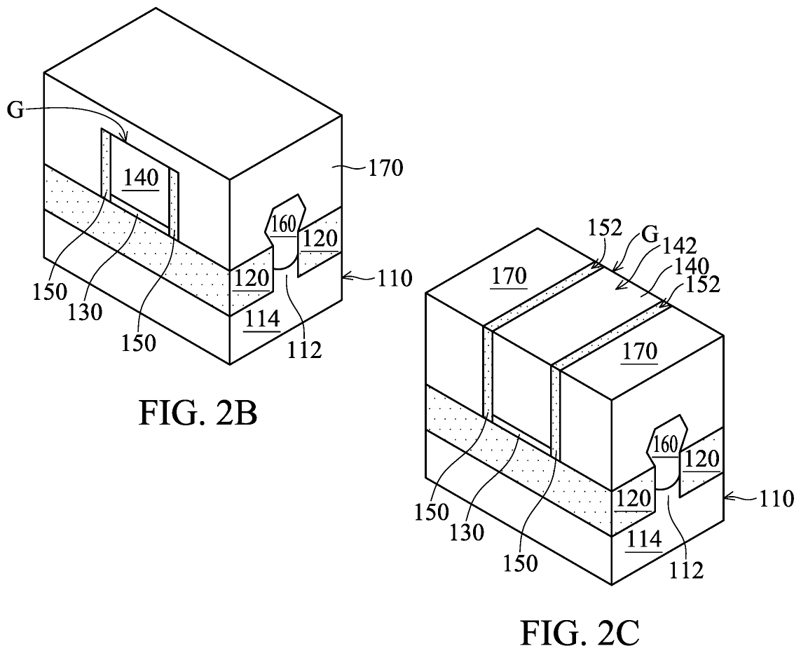

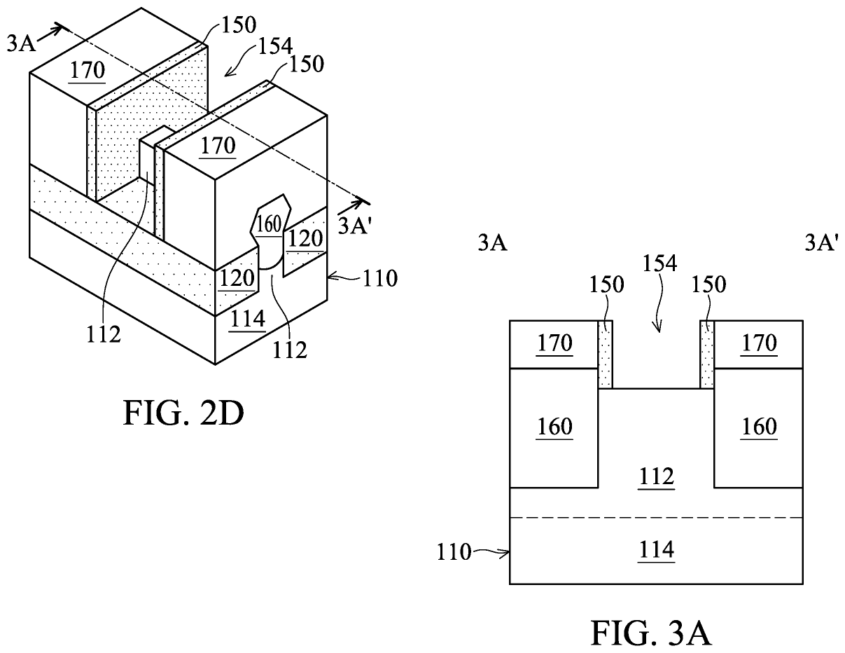

FIGS. 1A-1E are cross-sectional views of various stages of a process for forming a semiconductor device structure, in accordance with some embodiments. FIG. 1A-1 is a top view of the semiconductor device structure of FIG. 1A, in accordance with some embodiments. FIG. 1A is a cross-sectional view illustrating the semiconductor device structure along a sectional line I-I′ in FIG. 1A-1, in accordance with some embodiments. FIG. 1A-2 is a perspective view of the semiconductor device structure of FIG. 1A, in accordance with some embodiments.

As shown in FIGS. 1A, 1A-1, and 1A-2, a substrate 110 is provided, in accordance with some embodiments. The substrate 110 includes, for example, a semiconductor substrate. The semiconductor substrate includes, for example, a semiconductor wafer (such as a silicon wafer) or a portion of a semiconductor wafer.

In some embodiments, the substrate 110 is made of an elementary semiconductor material including silicon or germanium in a single crystal structure, a polycrystal structure, or an amorphous structure. In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIGS. 1A, 1A-1, and 1A-2, the substrate 110 has a fin portion 112 and a base portion 114, in accordance with some embodiments. The fin portion 112 is over the base portion 114, in accordance with some embodiments. As shown in FIG. 1A, an isolation layer 120 is formed over the base portion 114, in accordance with some embodiments.

The fin portion 112 is partially in the isolation layer 120, in accordance with some embodiments. The isolation layer 120 surrounds lower portions of the fin portion 112, in accordance with some embodiments. The isolation layer 120 includes oxide (such as silicon oxide), in accordance with some embodiments. The isolation layer 120 is formed by a chemical vapor deposition (CVD) process and an etching back process, in accordance with some embodiments.

As shown in FIG. 1B, a gate dielectric layer 130 is deposited over the isolation layer 120 and the fin portion 112, in accordance with some embodiments. The gate dielectric layer 130 conformally covers the isolation layer 120 and the fin portion 112, in accordance with some embodiments. The gate dielectric layer 130 is made of oxide, such as silicon oxide (e.g. SiO₂), in accordance with some embodiments. The gate dielectric layer 130 is also referred to as an oxide layer, in accordance with some embodiments.

The gate dielectric layer 130 is deposited using a chemical vapor deposition (CVD) process, a atomic layer deposition (ALD) process, a plasma enhanced atomic layer deposition (PEALD) process, or another suitable deposition process.

As shown in FIG. 1C, a gate electrode layer 140a is formed over the gate dielectric layer 130, in accordance with some embodiments. The gate electrode layer 140a is in direct contact with the gate dielectric layer 130, in accordance with some embodiments. The gate electrode layer 140a is made of polysilicon, in accordance with some embodiments. The gate electrode layer 140a is formed using a chemical vapor deposition process or another suitable process.

FIG. 1D-1 is a top view of the semiconductor device structure of FIG. 1D, in accordance with some embodiments. FIG. 1D is a cross-sectional view illustrating the semiconductor device structure along a sectional line I-I′ in FIG. 1D-1, in accordance with some embodiments. As shown in FIGS. 1D and 1D-1, a mask layer M is formed over the gate electrode layer 140a, in accordance with some embodiments. The mask layer M is made of a photoresist material or another suitable material, which is different from the material of the gate electrode layer 140a, in accordance with some embodiments.

FIG. 1E-1 is a top view of the semiconductor device structure of FIG. 1E, in accordance with some embodiments. FIG. 1E is a cross-sectional view illustrating the semiconductor device structure along a sectional line I-I′ in FIG. 1E-1, in accordance with some embodiments. FIG. 1E-2 is a perspective view of the semiconductor device structure of FIG. 1E, in accordance with some embodiments.

As shown in FIGS. 1D-1, 1E, 1E-1, and 1E-2, portions of the gate electrode layer 140a and the gate dielectric layer 130, which are not under the mask layer M, are removed, in accordance with some embodiments. After the removal process, the remaining gate electrode layer 140a forms a gate electrode 140, in accordance with some embodiments.

After the removal process, the gate electrode 140 and the remaining gate dielectric layer 130 together form a gate stack G, in accordance with some embodiments. Thereafter, as shown in FIGS. 1E, 1E-1, and 1E-2, the mask layer M is removed, in accordance with some embodiments.

Afterwards, as shown in FIGS. 1E, 1E-1, and 1E-2, a spacer layer 150 is formed over sidewalls S of the gate stack G, in accordance with some embodiments. The spacer layer 150 surrounds the gate stack G, in accordance with some embodiments. The spacer layer 150 is positioned over the fin portion 112 and the isolation layer 120, in accordance with some embodiments.

The spacer layer 150 includes insulating materials, such as silicon oxide, silicon nitride, silicon oxynitride, or silicon carbide, in accordance with some embodiments. The formation of the spacer layer 150 includes a deposition process and an anisotropic etching process, in accordance with some embodiments.

FIGS. 2A-2D are perspective views of various stages of a process for forming a semiconductor device structure, in accordance with some embodiments. After the step illustrated in FIG. 1E, as shown in FIG. 2A, the fin portion 112 is partially removed, in accordance with some embodiments. After the removal process, as shown in FIG. 2A, trenches 122 are formed in the isolation layer 120, in accordance with some embodiments.

As shown in FIG. 2A, source/drain structures 160 are formed in the trenches 122 and on the fin portion 112, in accordance with some embodiments. The source/drain structures 160 are in direct contact with the fin portion 112, in accordance with some embodiments. The source/drain structures 160 are positioned on two opposite sides of the gate stack G, in accordance with some embodiments. The source/drain structures 160 include a source structure and a drain structure, in accordance with some embodiments.

In some embodiments, the source/drain structures 160 are made of an N-type conductivity material. The N-type conductivity material includes silicon phosphorus (SiP) or another suitable N-type conductivity material. The source/drain structures 160 are formed using an epitaxial process, in accordance with some embodiments.

The source/drain structures 160 are doped with the Group VA element, in accordance with some embodiments. The Group VA element includes phosphor (P), antimony (Sb), or another suitable Group VA material. In some embodiments, a concentration of the Group VA element (e.g. phosphor) ranges from about 3E21 atoms/cm³ to about 7E21 atoms/cm³. The source/drain structures 160 are also referred to as doped structures, in accordance with some embodiments.

In some other embodiments, the source/drain structures 160 are made of a P-type conductivity material, in accordance with some embodiments. The P-type conductivity material includes silicon germanium (SiGe) or another suitable P-type conductivity material. The source/drain structures 160 are formed using an epitaxial process, in accordance with some embodiments. The source/drain structures 160 are doped with the Group IIIA element, in accordance with some embodiments. The Group IIIA element includes boron or another suitable material.

As shown in FIG. 2B, a dielectric layer 170 is formed over the gate stack G, the spacer layer 150, the isolation layer 120, and the source/drain structures 160, in accordance with some embodiments. The dielectric layer 170 includes oxide, such as silicon oxide (e.g., SiO₂), in accordance with some embodiments. The dielectric layer 170 is formed by a chemical vapor deposition (CVD) process, in accordance with some embodiments.

As shown in FIG. 2C, a planarization process is then performed on the dielectric layer 170 until a top surface 142 of the gate electrode 140 is exposed, in accordance with some embodiments. After the planarization process is performed, a top surface 152 of the spacer layer 150 is exposed, in accordance with some embodiments. The planarization process includes a chemical mechanical polishing (CMP) process, in accordance with some embodiments.

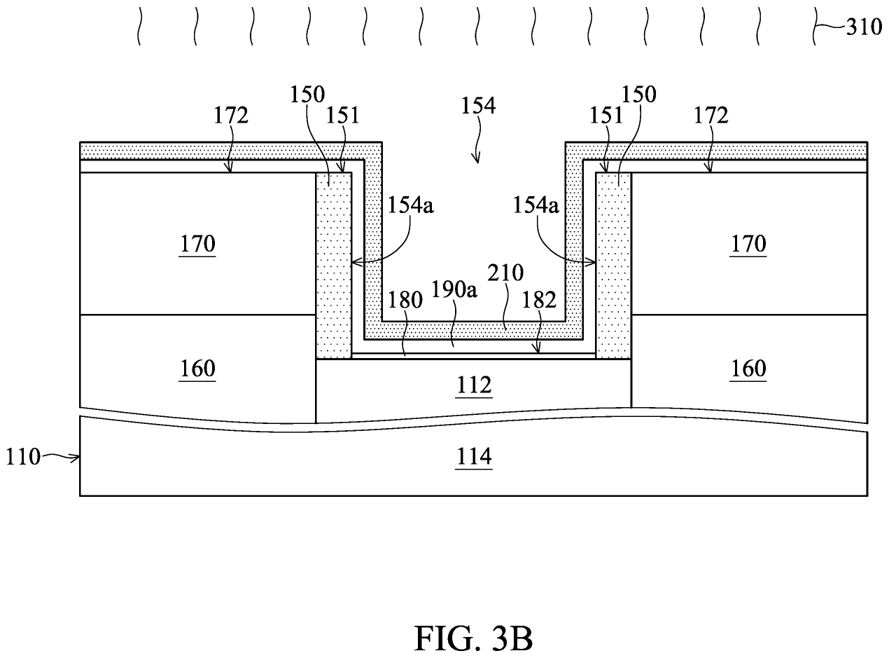

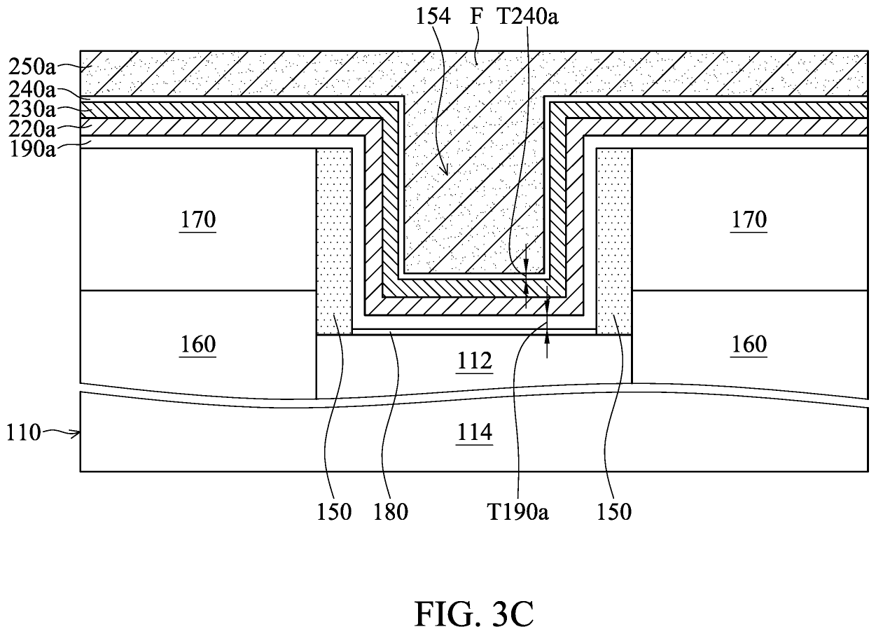

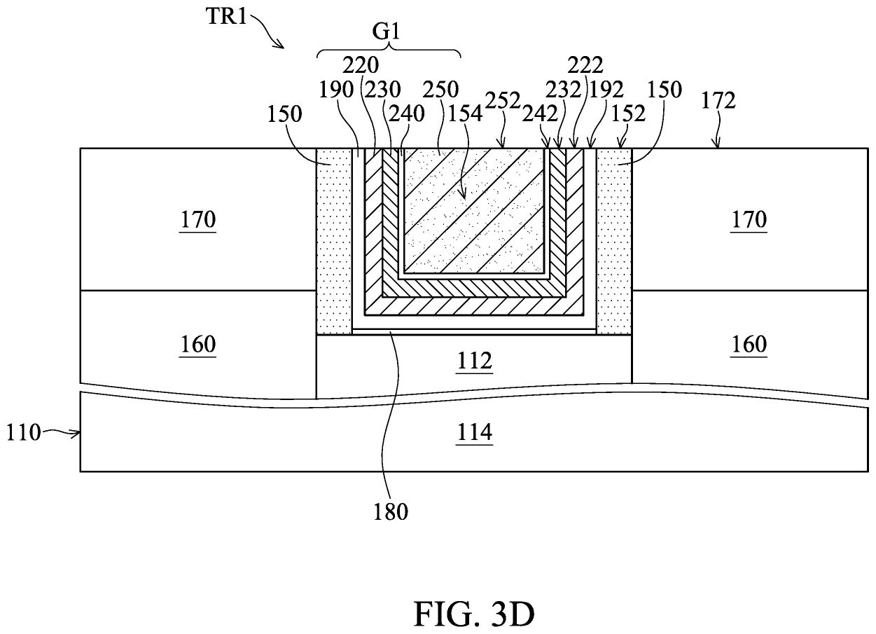

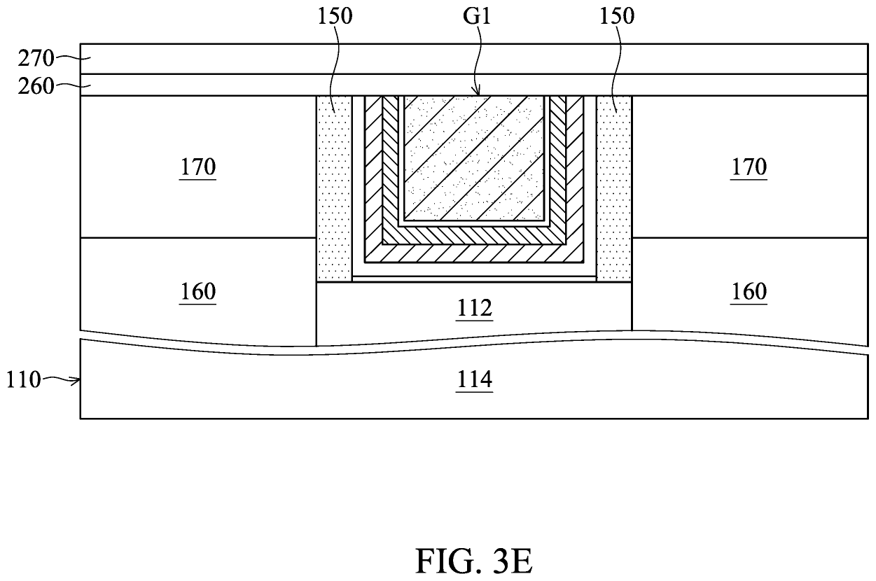

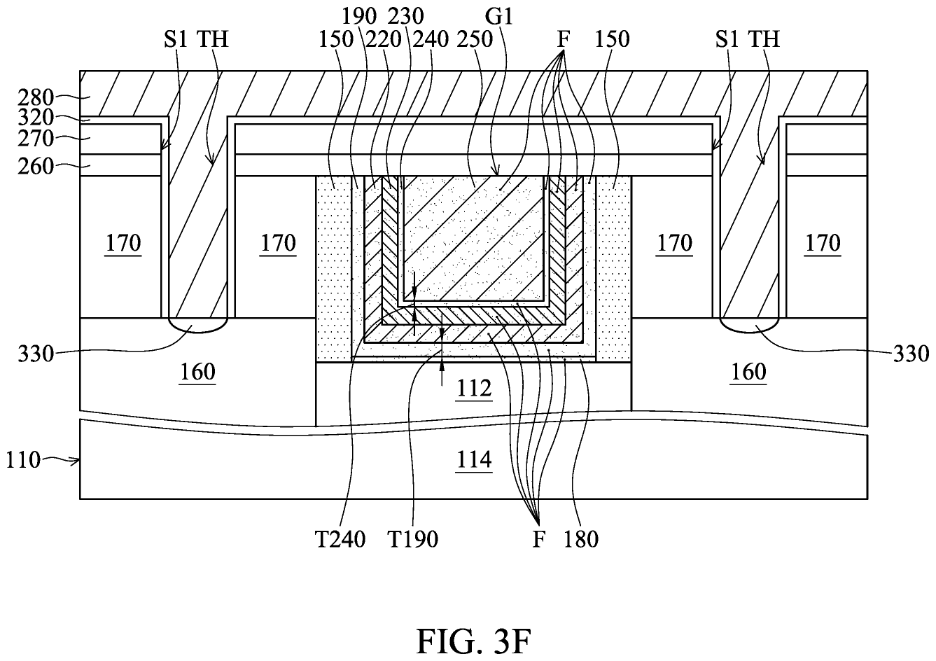

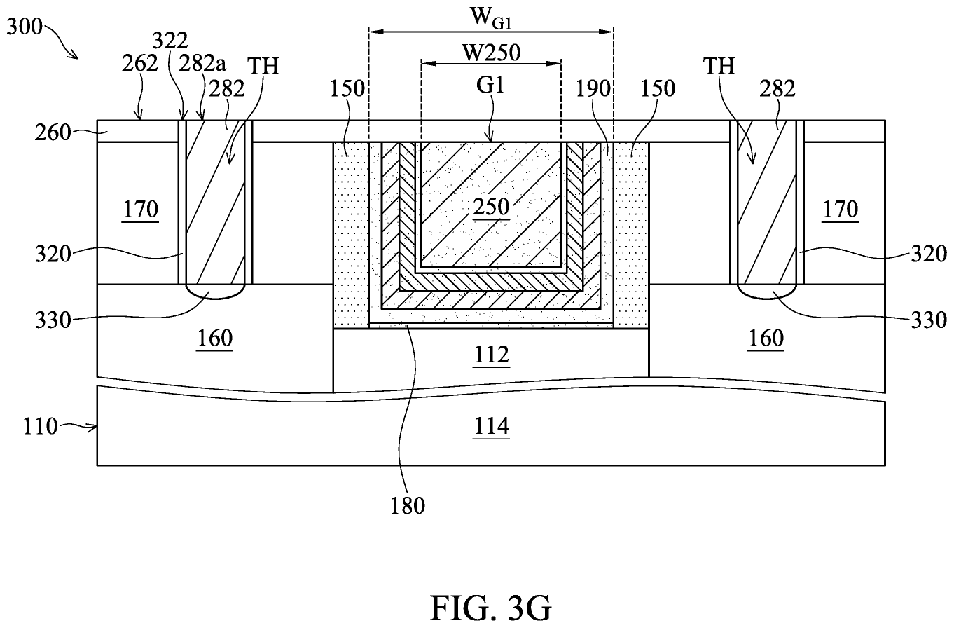

FIG. 3A is a cross-sectional view illustrating the semiconductor device structure along a sectional line 3A-3A′ in FIG. 2D, in accordance with some embodiments. As shown in FIGS. 2D and 3A, the gate electrode 140 is removed, in accordance with some embodiments. The removal process includes a wet etching process, in accordance with some embodiments. As shown in FIG. 2D, the gate dielectric layer 130 is removed, in accordance with some embodiments. The removal process includes a wet etching process, in accordance with some embodiments.

After the removal processes, a trench 154 is formed in the spacer layer 150, in accordance with some embodiments. The trench 154 exposes the fin portion 112 and the isolation layer 120, in accordance with some embodiments.

FIGS. 3A-3G are cross-sectional views of various stages of a process for forming a semiconductor device structure, in accordance with some embodiments. After the step of FIG. 3A, as shown in FIG. 3B, an interfacial layer 180 is formed over the fin portion 112, in accordance with some embodiments.

The interfacial layer 180 is used to improve the adhesion between the fin portion 112 and a gate dielectric layer subsequently formed thereon, in accordance with some embodiments. The interfacial layer 180 is made of semiconductor oxide such as silicon oxide, in accordance with some embodiments. The interfacial layer 180 is formed using an oxidation process, in accordance with some embodiments.

As shown in FIG. 3B, a gate dielectric material layer 190a is formed over the interfacial layer 180, the spacer layer 150, and the dielectric layer 170, in accordance with some embodiments. The gate dielectric material layer 190a conformally covers top surfaces 151 and 172 of the spacer layer 150 and the dielectric layer 170, inner walls 154a of the trench 154 in the spacer layer 150, and a top surface 182 of the interfacial layer 180, in accordance with some embodiments.

The gate dielectric material layer 190a is made of a high-K material, such as HfO₂, ZrO₂, HfZrO₂, or Al₂O₃, in accordance with some embodiments. The gate dielectric material layer 190a is formed using an atomic layer deposition process, a chemical vapor deposition process, or another suitable process.

As shown in FIG. 3B, a cap layer 210 is formed over the gate dielectric material layer 190a, in accordance with some embodiments. The cap layer 210 conformally covers the gate dielectric material layer 190a, in accordance with some embodiments. The cap layer 210 is made of a nitride material such as TiN, TiSiN, or TiN/Si, in accordance with some embodiments.

The cap layer 210 is formed using a deposition process such as a physical vapor deposition (PVD) process, a chemical vapor deposition (CVD) process, an atomic layer deposition (ALD), or a combination thereof, in accordance with some embodiments.

As shown in FIG. 3B, an annealing process 310 is performed over the cap layer 210 and the gate dielectric material layer 190a, in accordance with some embodiments. The annealing process 310 includes a rapid thermal process, in accordance with some embodiments. The rapid thermal process is performed at about 700° C. to about 1000° C., in accordance with some embodiments. The rapid thermal process is performed at about 800° C. to about 900° C., in accordance with some embodiments.

The cap layer 210 contains oxygen, and the cap layer 210 can be an oxygen source to compensate for the oxygen vacancy in the gate dielectric material layer 190a in the annealing process 310, in accordance with some embodiments. The gate dielectric material layer 190a becomes dense after the annealing process, in accordance with some embodiments. Therefore, the annealing process improves the stability, the dielectric property, and the reliability of the gate dielectric material layer 190a, in accordance with some embodiments. The TDDB (Time Dependent Dielectric Breakdown) performance is improved, in accordance with some embodiments.

As shown in FIG. 3C, the cap layer 210 is removed, in accordance with some embodiments. The cap layer 210 is removed using a wet etching process, in accordance with some embodiments. The wet etching process includes, for example, a first step, a second step, and a third step, in accordance with some embodiments.

The first step, the second step, and the third step are performed sequentially, in accordance with some embodiments. The etching solution used in the first step includes an HCl solution, in accordance with some embodiments. The etching solution used in the second step includes an HF solution, in accordance with some embodiments. The etching solution used in the third step includes an HCl solution, in accordance with some embodiments.

As shown in FIG. 3C, a work function metal material layer 220a is formed over the gate dielectric material layer 190a, in accordance with some embodiments. The work function metal material layer 220a conformally covers the gate dielectric material layer 190a, in accordance with some embodiments. The work function metal material layer 220a provides a desired work function for transistors to enhance device performance including improved threshold voltage.

In the embodiments of forming an NMOS transistor, the work function metal material layer 220a can be an n-type metal capable of providing a work function value suitable for the device, such as equal to or less than about 4.5 eV. The n-type metal may be made of metal, metal carbide, metal nitride, or a combination thereof. For example, the n-type metal is made of tantalum, tantalum nitride, or a combination thereof.

In the embodiments of forming a PMOS transistor, the work function metal material layer 220a can be a p-type metal capable of providing a work function value suitable for the device, such as equal to or greater than about 4.8 eV. The p-type metal may be made of metal, metal carbide, metal nitride, other suitable materials, or a combination thereof. For example, the p-type metal is made of titanium, titanium nitride, other suitable materials, or a combination thereof.

The work function metal material layer 220a is formed using a deposition process and a planarization process, in accordance with some embodiments. The deposition process includes a physical vapor deposition (PVD) process, a chemical vapor deposition (CVD) process, an atomic layer deposition (ALD), a plating process, another suitable method, or a combination thereof.

As shown in FIG. 3C, a work function metal material layer 230a is formed over the work function metal material layer 220a, in accordance with some embodiments. The work function metal material layer 230a conformally covers the work function metal material layer 220a, in accordance with some embodiments. The work function metal material layer 230a provides a desired work function for transistors to enhance device performance including improved threshold voltage.

In the embodiments of forming an NMOS transistor, the work function metal material layer 230a can be an n-type metal capable of providing a work function value suitable for the device, such as equal to or less than about 4.5 eV. The n-type metal may be made of metal, metal carbide, metal nitride, or a combination thereof. For example, the n-type metal is made of tantalum, tantalum nitride, or a combination thereof.

In the embodiments of forming a PMOS transistor, the work function metal material layer 230a can be a p-type metal capable of providing a work function value suitable for the device, such as equal to or greater than about 4.8 eV. The p-type metal may be made of metal, metal carbide, metal nitride, other suitable materials, or a combination thereof. For example, the p-type metal is made of titanium, titanium nitride, other suitable materials, or a combination thereof.

The work function metal material layer 230a is formed using a deposition process and a planarization process, in accordance with some embodiments. The deposition process includes a physical vapor deposition (PVD) process, a chemical vapor deposition (CVD) process, an atomic layer deposition (ALD), a plating process, another suitable method, or a combination thereof.

Afterwards, as shown in FIG. 3C, a glue material layer 240a is formed over the work function metal material layer 230a, in accordance with some embodiments. The glue material layer 240a is used to improve the adhesion between the work function metal material layer 230a and a gate electrode layer subsequently formed thereon, in accordance with some embodiments.

The glue material layer 240a conformally covers the work function metal material layer 230a, in accordance with some embodiments. The glue material layer 240a is thinner than the gate dielectric material layer 190a, in accordance with some embodiments. The thickness T240a of the glue material layer 240a is less than the thickness T190a of the gate dielectric material layer 190a, in accordance with some embodiments.

The thickness T240a ranges from about 9 nm to about 17 nm, in accordance with some embodiments. The thickness T240a ranges from about 11 nm to about 15 nm, in accordance with some embodiments. The thickness T190a ranges from about 10 nm to about 20 nm, in accordance with some embodiments. The thickness T190a ranges from about 12 nm to about 18 nm, in accordance with some embodiments.

The glue material layer 240a is made of nitride such as metal nitride (e.g., TiN), in accordance with some embodiments. The glue material layer 240a is formed using a deposition process such as a physical vapor deposition (PVD) process, a chemical vapor deposition (CVD) process, an atomic layer deposition (ALD), or a combination thereof, in accordance with some embodiments.

Afterwards, as shown in FIG. 3C, a gate electrode layer 250a (also called a metal gate electrode layer) is deposited over the glue material layer 240a to fill the trench 154, in accordance with some embodiments. The gate electrode layer 250a is made of a suitable metal material, such as tungsten or another suitable metal, an alloy thereof, or a combination thereof, in accordance with some embodiments.

The gate electrode layer 250a includes fluorine F, in accordance with some embodiments. The concentration (i.e., the atomic percentage) of the fluorine F within the gate electrode layer 250a ranges from about 0.1% to about 10%, in accordance with some embodiments.

If the concentration of the fluorine F within the gate electrode layer 250a is less than 0.1%, the fluorine F diffusing into the gate dielectric layer 190 would be too less to improve the dielectric property and the reliability of the gate dielectric layer 190 in the subsequent process, in accordance with some embodiments.

If the concentration of the fluorine F within the gate electrode layer 250a is greater than 10%, the fluorine F diffusing into the gate dielectric layer 190 is too much in the subsequent process, which adversely affects the electrical performance (e.g., the leakage current) of the gate dielectric layer 190, in accordance with some embodiments.

As shown in FIGS. 3C and 3D, upper portions of the gate electrode layer 250a, the glue material layer 240a, the work function metal material layer 230a, the work function metal material layer 220a, and the gate dielectric material layer 190a outside of the trench 154 of the spacer layer 150 are removed, in accordance with some embodiments. The remaining gate electrode layer 250a forms a gate electrode 250, in accordance with some embodiments. The remaining glue material layer 240a forms a glue layer 240, in accordance with some embodiments.

The remaining work function metal material layer 230a forms a work function metal layer 230, in accordance with some embodiments. The remaining work function metal material layer 220a forms a work function metal layer 220, in accordance with some embodiments. The remaining gate dielectric material layer 190a forms a gate dielectric layer 190, in accordance with some embodiments.

The gate electrode 250, the glue layer 240, the work function metal layers 220 and 230, the gate dielectric layer 190, and the interfacial layer 180 together form a gate stack G1, in accordance with some embodiments. The gate stack G1 and the source/drain structures 160 together form a transistor TR1, in accordance with some embodiments.

As shown in FIG. 3E, an etch stop layer 260 is formed over the dielectric layer 170, the spacer layer 150, and the gate stack G1, in accordance with some embodiments. The etch stop layer 260 is made of silicon nitride or another suitable material, in accordance with some embodiments.

The etch stop layer 260 is formed using a deposition process such as a physical vapor deposition (PVD) process, a chemical vapor deposition (CVD) process, an atomic layer deposition (ALD), or a combination thereof, in accordance with some embodiments.

As shown in FIG. 3E, a protective layer 270 is formed over the etch stop layer 260, in accordance with some embodiments. The protective layer 270 is configured to protect the etch stop layer 260 from being damaged during a subsequent pre-amorphized implantation (PAI) process, in accordance with some embodiments. The protective layer 270 includes, for example, a plasma-enhanced oxide (PEOX) layer.

Afterwards, as shown in FIG. 3F, portions of the dielectric layer 170, the etch stop layer 260, and the protective layer 270 are removed to form through holes TH passing through the dielectric layer 170, the etch stop layer 260, and the protective layer 270, in accordance with some embodiments. The through holes TH expose the source/drain structures 160, respectively, in accordance with some embodiments. In some embodiments, the removal process includes a photolithography process and an etching process.

As shown in FIG. 3F, a dielectric spacer liner (DSL) layer 320 is conformally formed on the protective layer 270 and the inner walls Si of the through holes TH, in accordance with some embodiments. The DSL layer 320 is configured to protect the inner walls Si from being damaged by a subsequent process, such as a pre-amorphized implantation (PAI) process. The DSL layer 320 is made of, for example, SiOC or another suitable material. The DSL layer 320 is formed by, for example, an atomic layer deposition process or another suitable process.

In some embodiments, a pre-amorphized implantation (PAI) process is performed to reduce the dopant channeling effect and enhance dopant activation. In some embodiments, silicon, germanium or carbon is used. In some other embodiments, inert gases, such as neon, argon, krypton, xenon, and/or radon, are used. Portions of the source/drain structures 160, exposed by the through holes TH, are turned into an amorphous state as a result of the PAI process, in accordance with some embodiments.

As shown in FIG. 3F, a salicidation (self-aligned silicidation) process is performed to form metal silicide structures 330 on/in the source/drain structures 160, respectively, in accordance with some embodiments. The metal silicide structures 330 are made of nickel silicide, in accordance with some embodiments.

In some embodiments, the metal silicide structures 330 are made of a silicide material of a suitable metal material. The suitable metal material may include cobalt (Co), nickel (Ni), platinum (Pt), titanium (Ti), ytterbium (Yb), molybdenum (Mo), erbium (Er), or a combination thereof. In some embodiments, the salicidation process is optional.

As shown in FIG. 3F, a conductive layer 280 is deposited over the DSL layer 320 to fill the through holes TH, in accordance with some embodiments. The conductive layer 280 is connected to the metal silicide structures 330, in accordance with some embodiments. The conductive layer 280 is made of, for example, tungsten or another suitable conductive material, in accordance with some embodiments. The conductive layer 280 is formed by, for example, a chemical vapor deposition (CVD) process, an atomic layer deposition (ALD) process, or another suitable process.

The process temperature of the chemical vapor deposition process or the atomic layer deposition process ranges from about 300° C. to about 500° C., in accordance with some embodiments. The process temperature of the chemical vapor deposition process or the atomic layer deposition process ranges from about 350° C. to about 450° C., in accordance with some embodiments.

During the deposition process of the conductive layer 280, the gate stack G1 is annealed, in accordance with some embodiments. Therefore, the fluorine F diffuses from the gate electrode 250 into the glue layer 240, the work function metal layer 230, the work function metal layer 220, the gate dielectric layer 190, and the interfacial layer 180, in accordance with some embodiments.

The deposition of the conductive layer 280 and the diffusion of the fluorine F from the gate electrode 250 into the glue layer 240, the work function metal layer 230, the work function metal layer 220, the gate dielectric layer 190, and the interfacial layer 180 are performed simultaneously, in accordance with some embodiments.

Since the thickness T240 of the glue layer 240 is thinner than the thickness T190 of the gate dielectric layer 190, a lot of the fluorine F diffuses from the gate electrode 250 into the gate dielectric layer 190, in accordance with some embodiments. In some embodiments, a fluorine concentration of the gate electrode 250 is greater than a fluorine concentration of the glue layer 240. The fluorine concentration of the glue layer 240 is greater than a fluorine concentration of the work function metal layer 230, in accordance with some embodiments.

The fluorine concentration of the work function metal layer 230 is greater than a fluorine concentration of the work function metal layer 220, in accordance with some embodiments. The fluorine concentration of the work function metal layer 220 is greater than a fluorine concentration of the gate dielectric layer 190, in accordance with some embodiments.

The fluorine concentration of the gate dielectric layer 190 is greater than a fluorine concentration of the interfacial layer 180, in accordance with some embodiments. That is, the fluorine concentration in the gate stack G1 continuously increases along a direction from the fin portion 112 or the spacer layer 150 toward the gate electrode 250, in accordance with some embodiments.

The fluorine F bonds to the dangling bonds of the gate dielectric layer 190, in accordance with some embodiments. Therefore, the stability, the dielectric property, and the reliability of the gate dielectric layer 190 are improved, in accordance with some embodiments.

In some embodiments, the fluorine F coming from the gate electrode 250 diffuses into the isolation layer 120 of FIG. 2D through the gate dielectric layer 190. The concentration of the fluorine F in the isolation layer 120 continuously increases along a direction from the isolation layer 120 toward the gate electrode 250, in accordance with some embodiments.

In some embodiments, the fluorine F coming from the gate electrode 250 diffuses into the fin portion 112. The concentration of the fluorine F in the fin portion 112 continuously increases along a direction from the fin portion 112 toward the gate electrode 250, in accordance with some embodiments.

The fluorine F bonds to the dangling bonds of the silicon of the fin portion 112, in accordance with some embodiments. Therefore, the stability and the reliability of the fin portion 112 are improved, in accordance with some embodiments.

As shown in FIGS. 3F and 3G, the conductive layer 280, the DSL layer 320 outside the through holes TH, and the protective layer 270 are removed, in accordance with some embodiments. The removal process includes, for example, a chemical mechanical polishing (CMP) process.

After the removal process, the conductive layer 280 remaining in the through holes TH forms contact plugs 282, in accordance with some embodiments. The contact plugs 282 are electrically connected to the source/drain structures 160 through the metal silicide structures 330, in accordance with some embodiments. After the removal process, top surfaces 262, 282a, and 322 of the etch stop layer 260, the contact plugs 282, and the DSL layer 320 are substantially level with each other, in accordance with some embodiments.

In this step, a semiconductor device structure 300 is substantially formed, in accordance with some embodiments. The semiconductor device structure 300 may be an n-type metal-oxide-semiconductor field-effect transistor (MOSFET) or a p-type MOSFET. Since the stability and the reliability of the gate dielectric layer 190 are improved, the stability and the reliability of the semiconductor device structure 300 are improved as well, in accordance with some embodiments.

As shown in FIG. 3G, the gate stack G1 has a width W_{G1} ranging from about 10 nm to about 25 nm, in accordance with some embodiments. The gate electrode 250 has a width W250 ranging from about 3 nm to about 13 nm, in accordance with some embodiments. In some embodiments, a ratio of the width W250 to the width W_{G1} ranges from about 0.4 to about 0.8, in accordance with some embodiments.

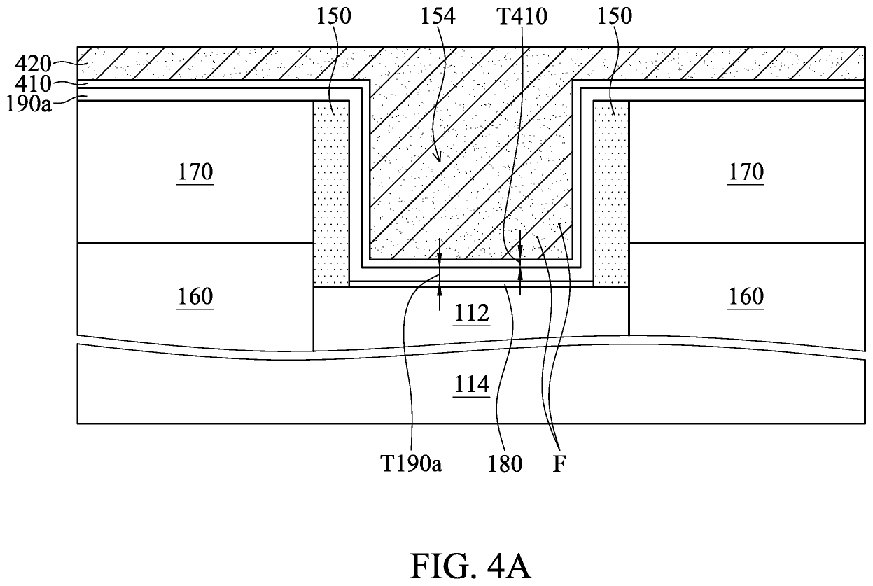

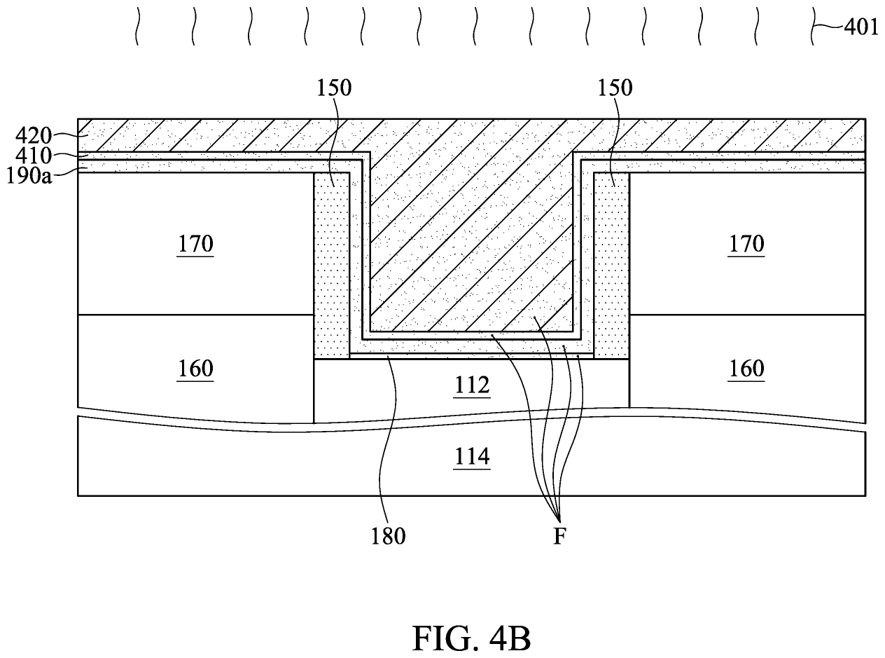

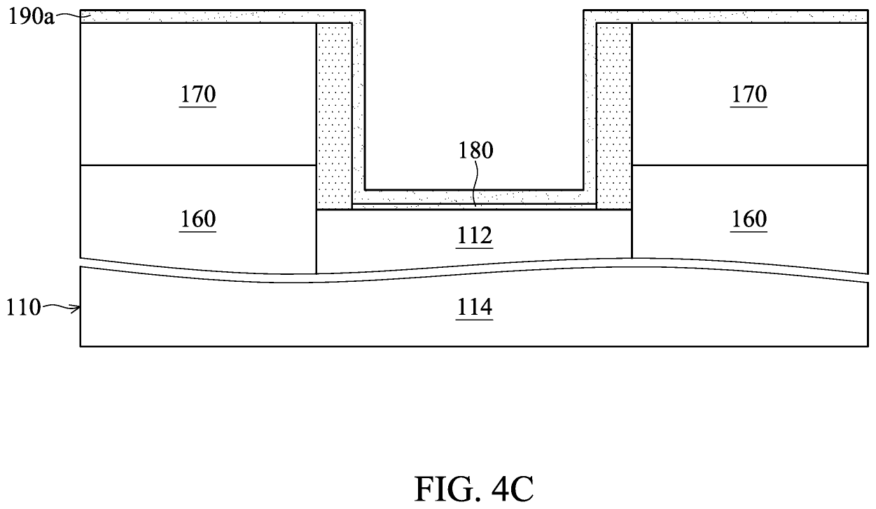

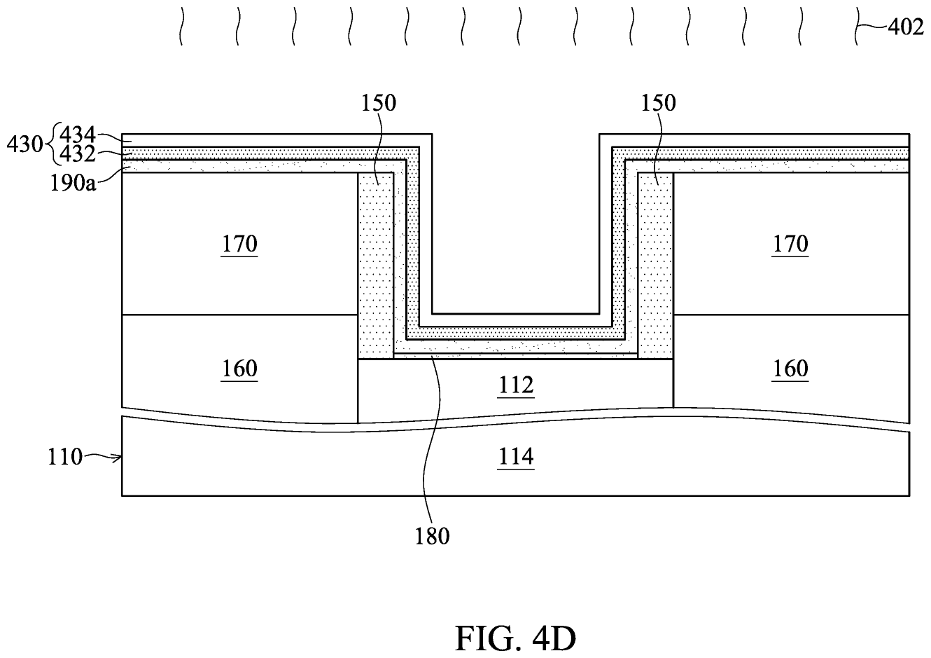

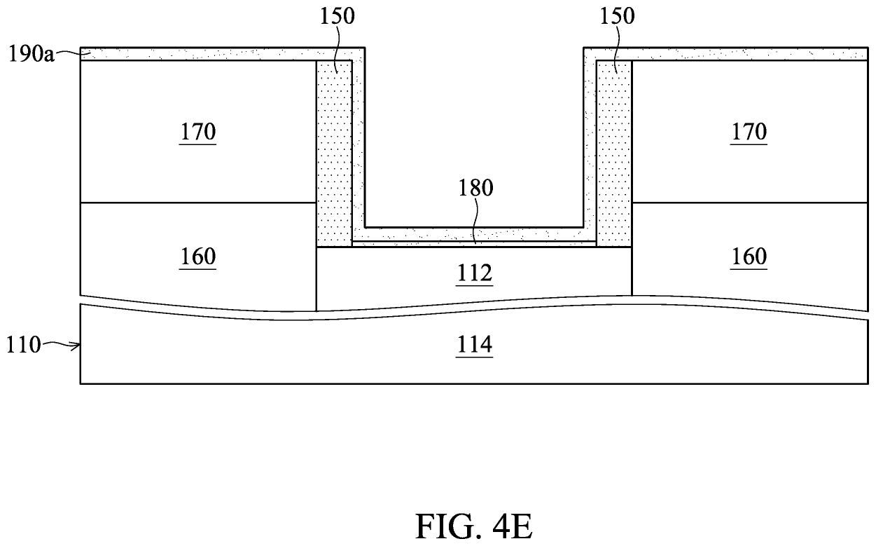

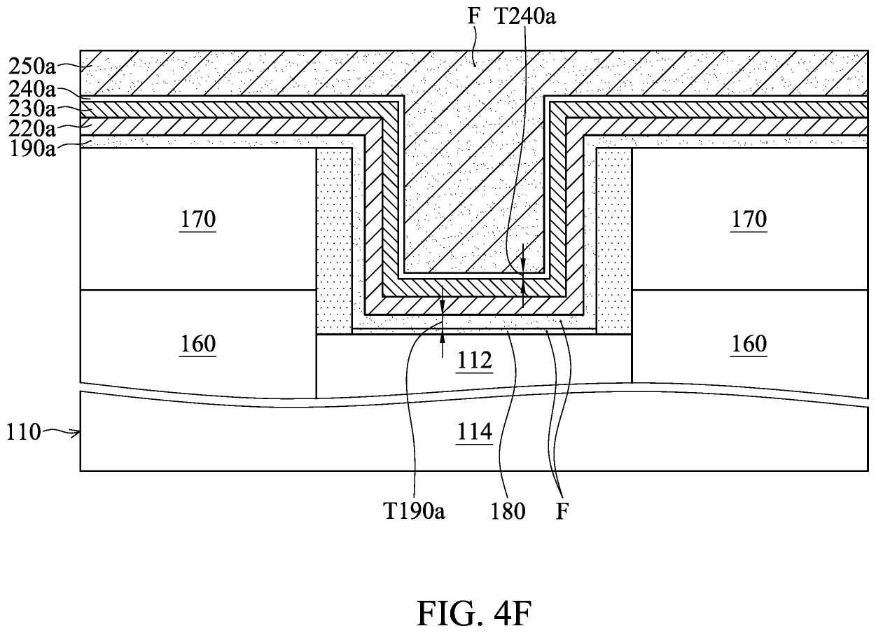

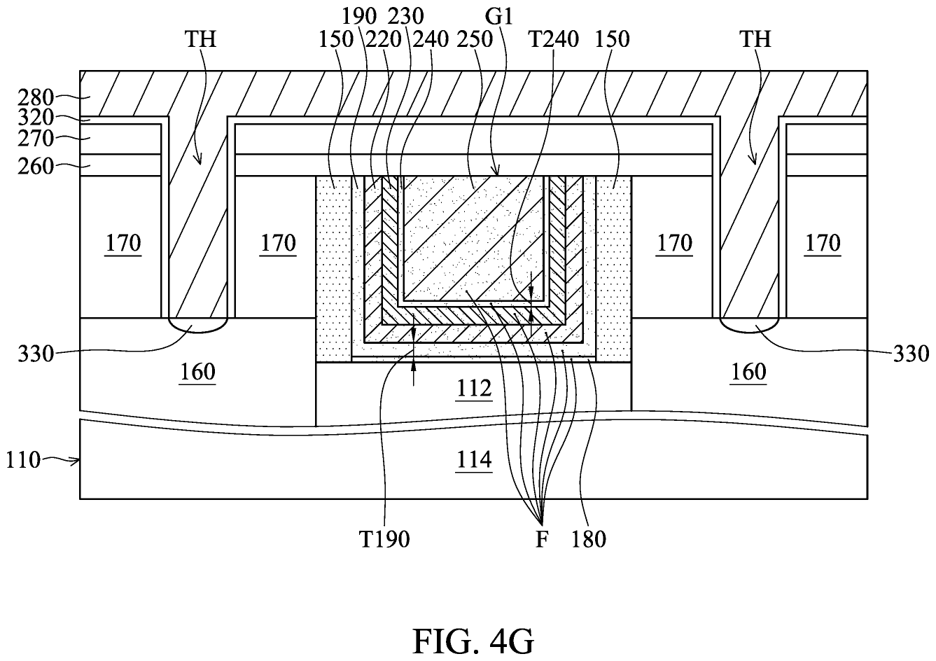

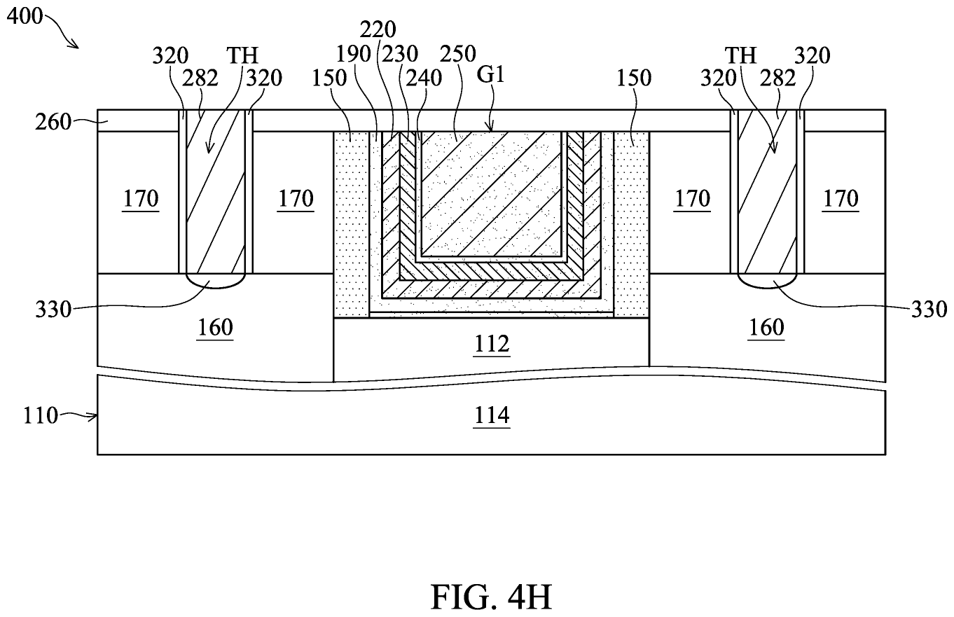

FIGS. 4A-4H are cross-sectional views of various stages of a process for is formed a semiconductor device structure, in accordance with some embodiments. As shown in FIG. 4A, the step of FIG. 3B is performed to form the interfacial layer 180 and the gate dielectric material layer 190a, in accordance with some embodiments.

As shown in FIG. 4A, a glue layer 410 is formed over the gate dielectric material layer 190a, in accordance with some embodiments. The glue layer 410 is used to improve the adhesion between the gate dielectric material layer 190a and a gate electrode layer subsequently formed thereon, in accordance with some embodiments.

The glue layer 410 conformally covers the gate dielectric material layer 190a, in accordance with some embodiments. The glue layer 410 is thinner than the gate dielectric material layer 190a, in accordance with some embodiments. The thickness T410 of the glue layer 410 is less than the thickness T190a of the gate dielectric material layer 190a, in accordance with some embodiments.

The thickness T410 ranges from about 9 nm to about 17 nm, in accordance with some embodiments. The thickness T410 ranges from about 11 nm to about 15 nm, in accordance with some embodiments. The thickness T190a ranges from about 10 nm to about 20 nm, in accordance with some embodiments. The thickness T190a ranges from about 12 nm to about 18 nm, in accordance with some embodiments.

The glue layer 410 is made of nitride such as metal nitride (e.g., TiN), in accordance with some embodiments. The glue layer 410 is formed using a deposition process such as a physical vapor deposition (PVD) process, a chemical vapor deposition (CVD) process, an atomic layer deposition (ALD), or a combination thereof, in accordance with some embodiments.

Afterwards, as shown in FIG. 4A, a gate electrode layer 420 (also called a metal gate electrode layer) is deposited over the glue layer 410 to fill the trench 154 of the spacer layer 150, in accordance with some embodiments. The gate electrode layer 420 is made of a suitable metal material, such as tungsten or another suitable metal, an alloy thereof, or a combination thereof, in accordance with some embodiments.

The gate electrode layer 420 includes fluorine F, in accordance with some embodiments. The concentration (i.e., the atomic percentage) of the fluorine F within the gate electrode layer 420 ranges from about 0.000001% to about 10%, in accordance with some embodiments. The concentration of the fluorine F within the gate electrode layer 420 ranges from about 0.1% to about 10%, in accordance with some embodiments. The concentration of the fluorine F within the gate electrode layer 420 ranges from about 0.1% to about 1%, in accordance with some embodiments.

As shown in FIG. 4B, an annealing process 401 is performed over the gate electrode layer 420, the glue layer 410, the gate dielectric material layer 190a, and the interfacial layer 180, in accordance with some embodiments. Therefore, the fluorine F diffuses from the gate electrode layer 420 into the glue layer 410, the gate dielectric material layer 190a, and the interfacial layer 180, in accordance with some embodiments. Since the glue layer 410 is thinner than the gate dielectric material layer 190a, a lot of the fluorine F diffuses from the gate electrode layer 420 into the gate dielectric material layer 190a, in accordance with some embodiments.

The annealing process 401 includes a rapid thermal process, in accordance with some embodiments. The rapid thermal process is performed at about 700° C. to about 1000° C., in accordance with some embodiments. The rapid thermal process is performed at about 800° C. to about 900° C., in accordance with some embodiments.

As shown in FIG. 4C, the glue layer 410 and the gate electrode layer 420 are removed, in accordance with some embodiments. The removal process of the gate electrode layer 420 uses an etching solution including ozonated DI-water (DIO₃), in accordance with some embodiments. The temperature of the ozonated DI-water is maintained at room temperature, in accordance with some embodiments. The processing time of the removal process ranges from about 30 s to about 270 s, in accordance with some embodiments.

The removal process of the glue layer 410 uses an etching solution including H₂O₂, in accordance with some embodiments. The temperature of the H₂O₂ solution is maintained between about 40° C. to about 70° C., in accordance with some embodiments. The processing time of the removal process ranges from about 60 s to about 180 s, in accordance with some embodiments.

As shown in FIG. 4D, a cap layer 430 is formed over the gate dielectric material layer 190a, in accordance with some embodiments. The cap layer 430 includes a lower layer 432 and an upper layer 434 over the lower layer 432, in accordance with some embodiments. The lower layer 432 is made of nitride such as TiN, in accordance with some embodiments. The upper layer 434 is made of a semiconductor material such as silicon, in accordance with some embodiments.

The lower layer 432 and the upper layer 434 are formed using deposition processes such as a physical vapor deposition (PVD) process, a chemical vapor deposition (CVD) process, an atomic layer deposition (ALD), and/or a combination thereof.

As shown in FIG. 4D, an annealing process 402 is performed over the cap layer 430 and the gate dielectric material layer 190a, in accordance with some embodiments. The annealing process 402 includes a rapid thermal process, in accordance with some embodiments. The rapid thermal process is performed at about 700° C. to about 1000° C., in accordance with some embodiments. The rapid thermal process is performed at about 800° C. to about 900° C., in accordance with some embodiments.

The cap layer 430 contains oxygen, and the cap layer 430 can be an oxygen source to compensate for the oxygen vacancy in the gate dielectric material layer 190a in the annealing process 402, in accordance with some embodiments. The gate dielectric material layer 190a becomes dense after the annealing process, in accordance with some embodiments. Therefore, the annealing process improves the stability, the dielectric property, and the reliability of the gate dielectric material layer 190a, in accordance with some embodiments.

As shown in FIG. 4E, the cap layer 430 is removed, in accordance with some embodiments. The removal process includes a dry etching process or a wet etching process, in accordance with some embodiments.

As shown in FIG. 4F, the step of FIG. 3C is performed to sequentially form the work function metal material layer 220a, the work function metal material layer 230a, the glue material layer 240a, and the gate electrode layer 250a over the gate dielectric material layer 190a, in accordance with some embodiments.

The glue material layer 240a is thinner than the gate dielectric material layer 190a, in accordance with some embodiments. That is, the thickness T240a of the glue material layer 240a is less than the thickness T190a of the gate dielectric material layer 190a, in accordance with some embodiments. The gate electrode layer 250a includes fluorine F, in accordance with some embodiments.

As shown in FIG. 4G, the steps of FIGS. 3D-3F are performed to sequentially form the etch stop layer 260, the protective layer 270, the DSL layer 320, the metal silicide structures 330, and the conductive layer 280, in accordance with some embodiments.

During the deposition process of the conductive layer 280, the gate stack G1 is annealed, in accordance with some embodiments. Therefore, the fluorine F diffuses from the gate electrode 250 into the glue layer 240, the work function metal layer 230, the work function metal layer 220, the gate dielectric layer 190, and the interfacial layer 180, in accordance with some embodiments.

The deposition of the conductive layer 280 and the diffusion of the fluorine F from the gate electrode 250 into the glue layer 240, the work function metal layer 230, the work function metal layer 220, the gate dielectric layer 190, and the interfacial layer 180 are performed simultaneously, in accordance with some embodiments.

As shown in FIG. 4H, the step of FIG. 3G is performed to remove the conductive layer 280, the DSL layer 320 outside the through holes TH, and the protective layer 270, in accordance with some embodiments. In this step, a semiconductor device structure 400 is substantially formed, in accordance with some embodiments.

The semiconductor device structure 400 may be an n-type metal-oxide-semiconductor field-effect transistor (MOSFET) or a p-type MOSFET. Since the stability and the reliability of the gate dielectric layer 190 are improved, the stability and the reliability of the semiconductor device structure 400 are improved as well, in accordance with some embodiments.

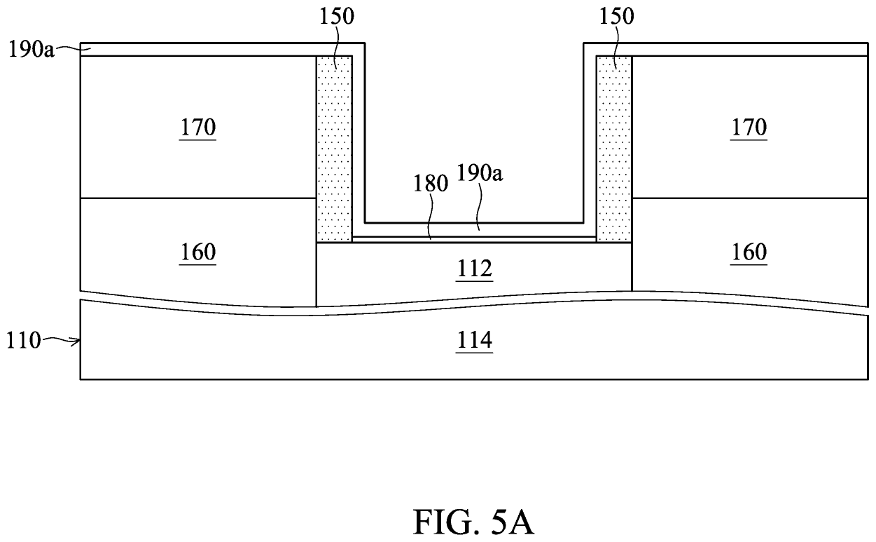

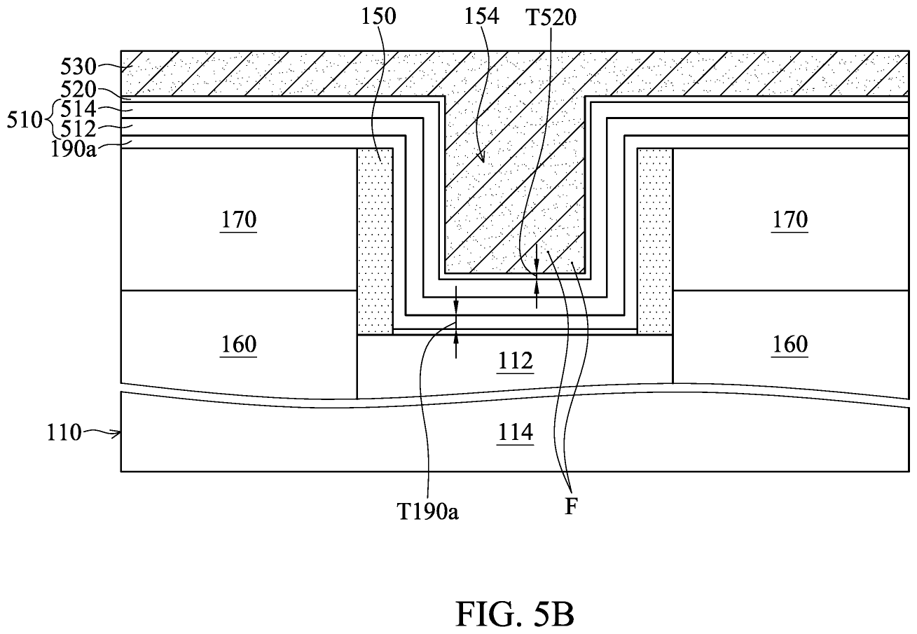

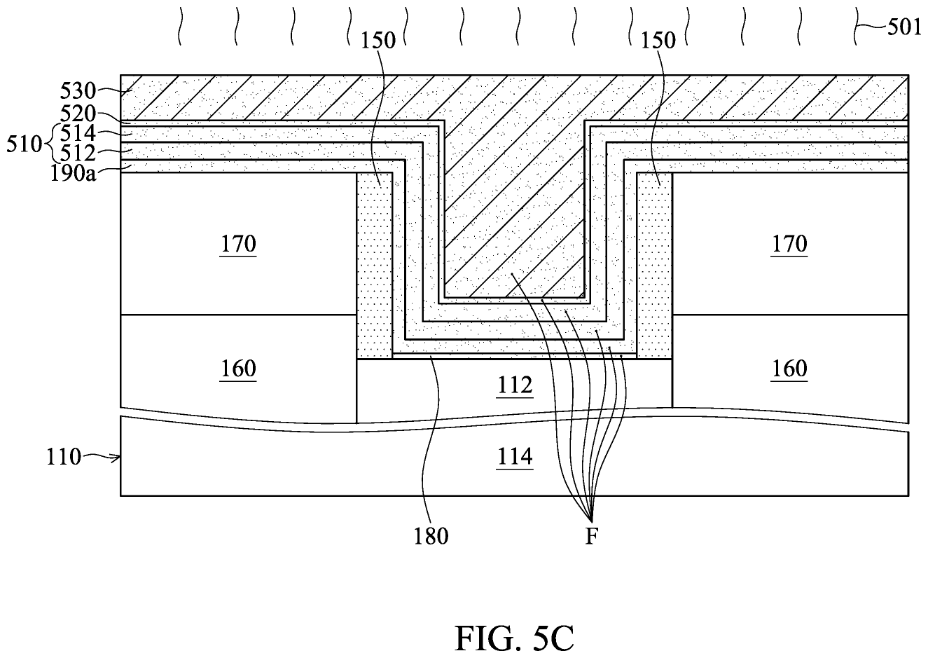

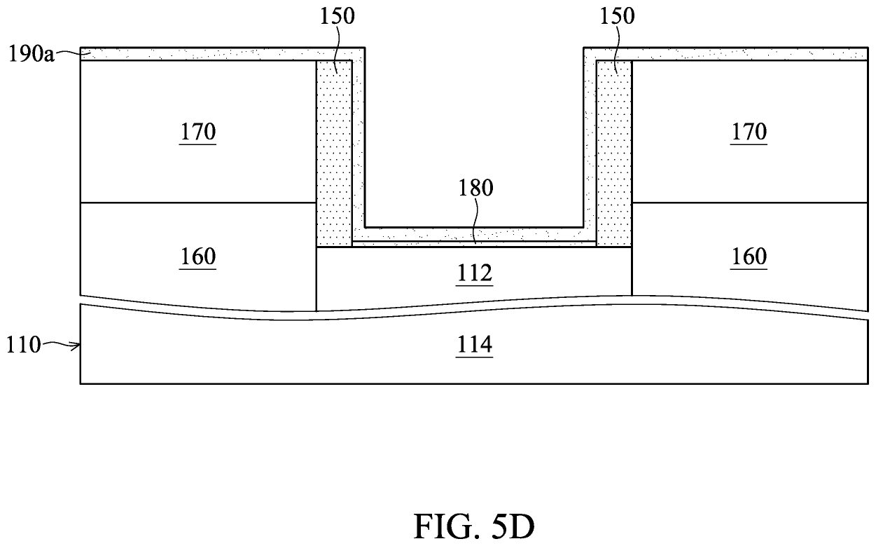

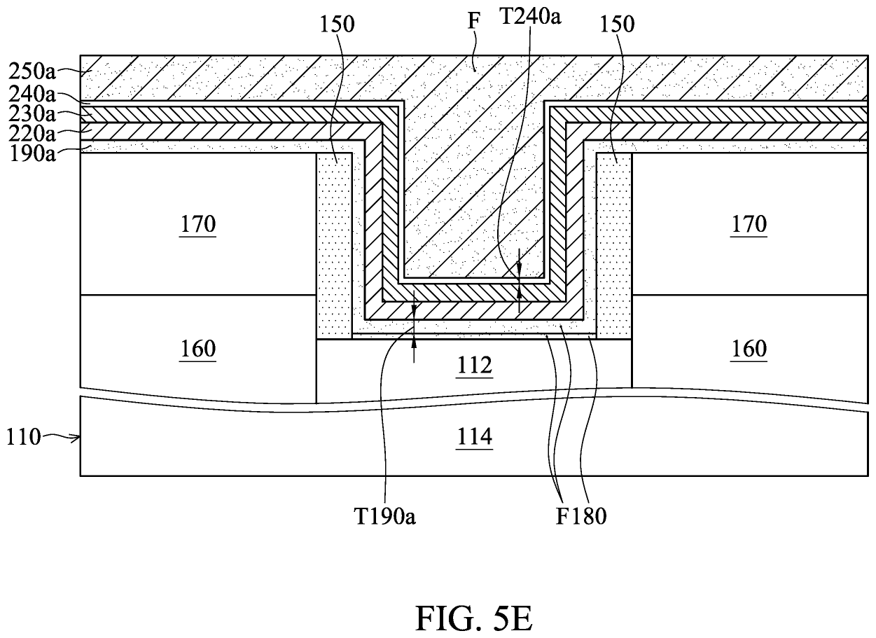

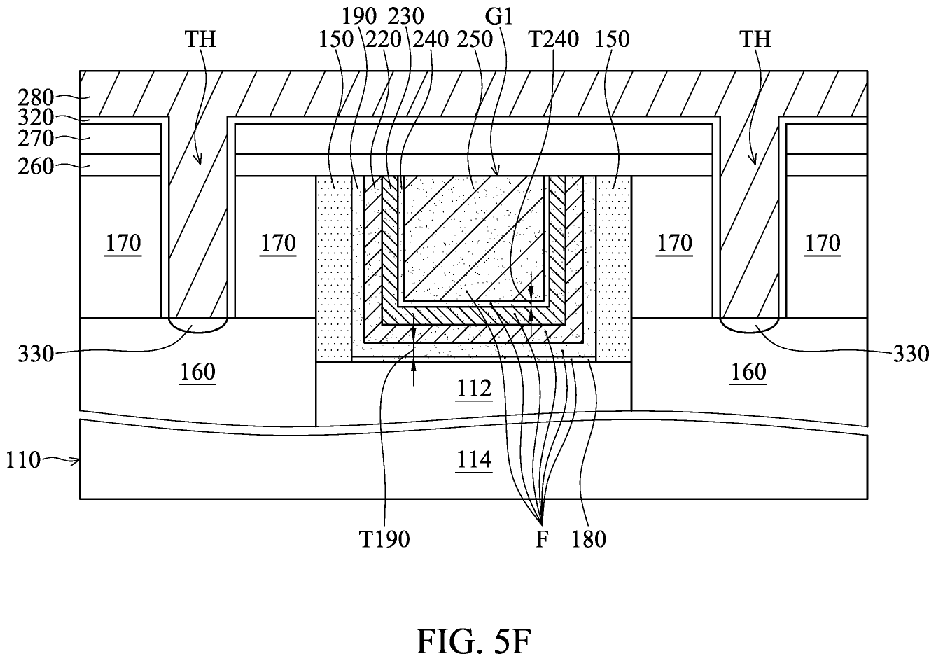

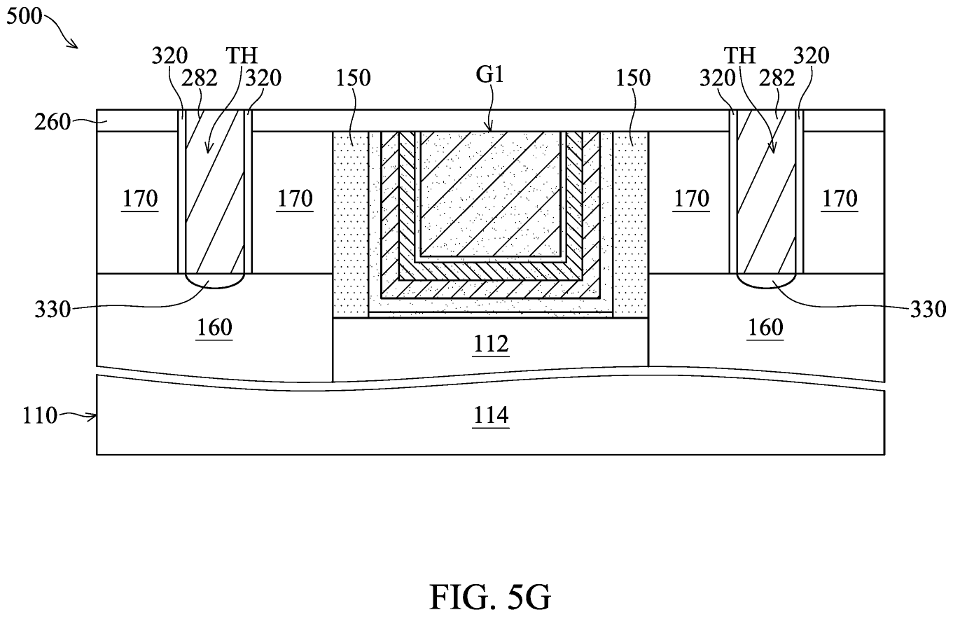

FIGS. 5A-5G are cross-sectional views of various stages of a process for is formed a semiconductor device structure, in accordance with some embodiments. As shown in FIG. 5A, the step of FIG. 3B is performed to form the interfacial layer 180 and the gate dielectric material layer 190a, in accordance with some embodiments.

As shown in FIG. 5B, a cap layer 510 is formed over the gate dielectric material layer 190a, in accordance with some embodiments. The cap layer 510 includes a lower layer 512 and an upper layer 514 over the lower layer 512, in accordance with some embodiments. The lower layer 512 is made of nitride such as TiN, in accordance with some embodiments. The upper layer 514 is made of a semiconductor material such as silicon, in accordance with some embodiments.

The lower layer 512 and the upper layer 514 are formed using deposition processes such as a physical vapor deposition (PVD) process, a chemical vapor deposition (CVD) process, an atomic layer deposition (ALD), and/or a combination thereof.

As shown in FIG. 5B, a glue layer 520 is formed over the cap layer 510, in accordance with some embodiments. The glue layer 520 is used to improve the adhesion between the cap layer 510 and a gate electrode layer subsequently formed thereon, in accordance with some embodiments.

The glue layer 520 conformally covers the cap layer 510, in accordance with some embodiments. The glue layer 520 is thinner than the gate dielectric material layer 190a, in accordance with some embodiments. The thickness T520 of the glue layer 520 is less than the thickness T190a of the gate dielectric material layer 190a, in accordance with some embodiments.

The thickness T520 ranges from about 9 nm to about 17 nm, in accordance with some embodiments. The thickness T520 ranges from about 11 nm to about 15 nm, in accordance with some embodiments. The thickness T190a ranges from about 10 nm to about 20 nm, in accordance with some embodiments. The thickness T190a ranges from about 12 nm to about 18 nm, in accordance with some embodiments.

The glue layer 520 is made of nitride such as metal nitride (e.g., TiN), in accordance with some embodiments. The glue layer 520 is formed using a deposition process such as a physical vapor deposition (PVD) process, a chemical vapor deposition (CVD) process, an atomic layer deposition (ALD), or a combination thereof, in accordance with some embodiments.

Afterwards, as shown in FIG. 5B, a gate electrode layer 530 (also called a metal gate electrode layer) is deposited over the glue layer 520 to fill the trench 154 of the spacer layer 150, in accordance with some embodiments. The gate electrode layer 530 is made of a suitable metal material, such as tungsten or another suitable metal, an alloy thereof, or a combination thereof, in accordance with some embodiments.

The gate electrode layer 530 includes fluorine F, in accordance with some embodiments. The concentration (i.e., the atomic percentage) of the fluorine F within the gate electrode layer 530 ranges from about 0.000001% to about 10%, in accordance with some embodiments. The concentration of the fluorine F within the gate electrode layer 530 ranges from about 0.1% to about 10%, in accordance with some embodiments. The concentration of the fluorine F within the gate electrode layer 530 ranges from about 0.1% to about 1%, in accordance with some embodiments.

As shown in FIG. 5C, an annealing process 501 is performed over the gate electrode layer 530, the glue layer 520, the cap layer 510, the gate dielectric material layer 190a, and the interfacial layer 180, in accordance with some embodiments. Therefore, the fluorine F diffuses from the gate electrode layer 530 into the glue layer 520, the cap layer 510, the gate dielectric material layer 190a, and the interfacial layer 180, in accordance with some embodiments. Since the glue layer 520 is thinner than the gate dielectric material layer 190a, a lot of the fluorine F diffuses from the gate electrode layer 530 into the gate dielectric material layer 190a, in accordance with some embodiments.

The annealing process 501 includes a rapid thermal process, in accordance with some embodiments. The rapid thermal process is performed at about 700° C. to about 1000° C., in accordance with some embodiments. The rapid thermal process is performed at about 800° C. to about 900° C., in accordance with some embodiments.

As shown in FIG. 5D, the cap layer 510, the glue layer 520 and the gate electrode layer 530 are removed, in accordance with some embodiments. The removal process of the gate electrode layer 530 uses an etching solution including ozonated DI-water (DIO3), in accordance with some embodiments. The temperature of the ozonated DI-water is maintained at room temperature, in accordance with some embodiments. The processing time of the removal process ranges from about 30 s to about 270 s, in accordance with some embodiments.

The removal process of the glue layer 520 uses an etching solution including H₂O₂, in accordance with some embodiments. The temperature of the H₂O₂ solution is maintained between about 40° C. to about 70° C., in accordance with some embodiments. The processing time of the removal process ranges from about 60 s to about 180 s, in accordance with some embodiments. The removal process of the cap layer 510 includes a dry etching process or a wet etching process, in accordance with some embodiments.

As shown in FIG. 5E, the step of FIG. 3C is performed to sequentially form the work function metal material layer 220a, the work function metal material layer 230a, the glue material layer 240a, and the gate electrode layer 250a over the gate dielectric material layer 190a, in accordance with some embodiments.

The glue material layer 240a is thinner than the gate dielectric material layer 190a, in accordance with some embodiments. That is, the thickness T240a of the glue material layer 240a is less than the thickness T190a of the gate dielectric material layer 190a, in accordance with some embodiments. The gate electrode layer 250a includes fluorine F, in accordance with some embodiments.

As shown in FIG. 5F, the steps of FIGS. 3D-3F are performed to sequentially form the etch stop layer 260, the protective layer 270, the DSL layer 320, the metal silicide structures 330, and the conductive layer 280, in accordance with some embodiments.

During the deposition process of the conductive layer 280, the gate stack G1 is annealed, in accordance with some embodiments. Therefore, the fluorine F diffuses from the gate electrode 250 into the glue layer 240, the work function metal layer 230, the work function metal layer 220, the gate dielectric layer 190, and the interfacial layer 180, in accordance with some embodiments.

The deposition of the conductive layer 280 and the diffusion of the fluorine F from the gate electrode 250 into the glue layer 240, the work function metal layer 230, the work function metal layer 220, the gate dielectric layer 190, and the interfacial layer 180 are performed simultaneously, in accordance with some embodiments.

As shown in FIG. 5G, the step of FIG. 3G is performed to remove the conductive layer 280, the DSL layer 320 outside the through holes TH, and the protective layer 270, in accordance with some embodiments. In this step, a semiconductor device structure 500 is substantially formed, in accordance with some embodiments.

The semiconductor device structure 500 may be an n-type metal-oxide-semiconductor field-effect transistor (MOSFET) or a p-type MOSFET. Since the stability and the reliability of the gate dielectric layer 190 are improved, the stability and the reliability of the semiconductor device structure 400 are improved as well, in accordance with some embodiments.

Processes and materials for forming the semiconductor device structures 400 and 500 may be similar to, or the same as, those for forming the semiconductor device structure 300 described above. Elements designated by the same or similar reference numbers as those in FIGS. 1A to 5G have the same or similar structures and the materials. Therefore, the detailed descriptions thereof will not be repeated herein.

In accordance with some embodiments, semiconductor device structures and methods for forming the same are provided. The methods (for forming the semiconductor device structure) form a thin glue layer between a gate electrode containing fluorine and a gate dielectric layer. Since the glue layer is thin, a lot of the fluorine diffuses from the gate electrode into the gate dielectric layer in an annealing process. The fluorine bonds to the dangling bonds of the gate dielectric layer, which improves the stability, the dielectric property, and the reliability of the gate dielectric layer.

In accordance with some embodiments, a method for forming a semiconductor device structure is provided. The method includes forming a gate dielectric layer over a substrate. The method includes forming a work function metal layer over the gate dielectric layer. The method includes forming a glue layer over the work function metal layer. The glue layer is thinner than the gate dielectric layer. The method includes forming a gate electrode over the glue layer. The gate electrode comprises fluorine. The method includes annealing the gate electrode. The fluorine diffuses from the gate electrode into the gate dielectric layer.

In accordance with some embodiments, a method for forming a semiconductor device structure is provided. The method includes forming a gate dielectric layer over a substrate. The method includes forming a first glue layer over the gate dielectric layer. The glue layer is thinner than the gate dielectric layer. The method includes forming a gate electrode layer over the first glue layer. The gate electrode layer comprises fluorine. The method includes annealing the gate electrode layer. The fluorine diffuses from the gate electrode layer into the gate dielectric layer. The method includes removing the gate electrode layer and the first glue layer. The method includes forming a work function metal layer over the gate dielectric layer. The method includes forming a second glue layer over the work function metal layer. The method includes forming a gate electrode over the second glue layer.

In accordance with some embodiments, a semiconductor device structure is provided. The semiconductor device structure includes a substrate. The semiconductor device structure includes a gate dielectric layer over the substrate. The gate dielectric layer comprises fluorine. The semiconductor device structure includes a work function metal layer over the gate dielectric layer. The semiconductor device structure includes a glue layer over the work function metal layer. The glue layer is thinner than the gate dielectric layer. The semiconductor device structure includes a gate electrode over the glue layer. The gate electrode comprises fluorine.

The fluorine Foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a gate dielectric layer over a substrate;
forming a work function metal layer over the gate dielectric layer;
forming a glue layer over the work function metal layer, wherein the glue layer is thinner than the gate dielectric layer;
forming a gate electrode over the glue layer, wherein the gate electrode comprises fluorine; and
annealing the gate electrode, wherein the fluorine diffuses from the gate electrode into the gate dielectric layer.

2. The method for forming the semiconductor device structure as claimed in claim 1, further comprising:
forming a dielectric layer over the substrate before forming the gate dielectric layer over the substrate, wherein the dielectric layer has a trench, and the gate dielectric layer is formed in the trench.

3. The method for forming the semiconductor device structure as claimed in claim 2, further comprising:
forming an etch stop layer over the dielectric layer, the gate dielectric layer, the work function metal layer, the glue layer, and the gate electrode before annealing the gate electrode; and
forming a protective layer over the etch stop layer.

4. The method for forming the semiconductor device structure as claimed in claim 3, further comprising:
removing portions of the dielectric layer, the etch stop layer, and the protective layer to form a through hole passing through the dielectric layer, the etch stop layer, and the protective layer;
depositing a conductive layer over the protective layer and in the through hole; and
removing the protective layer and the conductive layer outside of the through hole.

5. The method for forming the semiconductor device structure as claimed in claim 4, wherein the depositing of the conductive layer over the protective layer and in the through hole comprises the annealing of the gate electrode.

6. The method for forming the semiconductor device structure as claimed in claim 5, wherein the depositing of the conductive layer over the protective layer and in the through hole and the diffusion of the fluorine from the gate electrode into the gate dielectric layer are performed simultaneously.

7. The method for forming the semiconductor device structure as claimed in claim 1, wherein the fluorine further diffuses from the gate electrode into the work function metal layer after annealing the gate electrode.

8. The method for forming the semiconductor device structure as claimed in claim 1, wherein the fluorine further diffuses from the gate electrode into the glue layer after annealing the gate electrode.

9. The method for forming the semiconductor device structure as claimed in claim 1, wherein a first fluorine concentration of the gate electrode is greater than a second fluorine concentration of the gate dielectric layer after annealing the gate electrode.

10. The method for forming the semiconductor device structure as claimed in claim 1, further comprising:
forming a cap layer over the gate dielectric layer;
annealing the gate dielectric layer and the cap layer; and
removing the cap layer before forming the work function metal layer over the gate dielectric layer.

11. A method for forming a semiconductor device structure, comprising:
forming a gate dielectric layer over a substrate;
forming a first glue layer over the gate dielectric layer, wherein the first glue layer is thinner than the gate dielectric layer;
forming a gate electrode layer over the first glue layer, wherein the gate electrode layer comprises fluorine;
annealing the gate electrode layer, wherein the fluorine diffuses from the gate electrode layer into the gate dielectric layer;
removing the gate electrode layer and the first glue layer;
forming a work function metal layer over the gate dielectric layer;
forming a second glue layer over the work function metal layer; and
forming a gate electrode over the second glue layer.

12. The method for forming the semiconductor device structure as claimed in claim 11, wherein the second glue layer is thinner than the gate dielectric layer.

13. The method for forming the semiconductor device structure as claimed in claim 11, wherein the gate electrode comprises fluorine.

14. The method for forming the semiconductor device structure as claimed in claim 11, further comprising:
forming a cap layer over the gate dielectric layer after removing the gate electrode layer and the first glue layer;
annealing the gate dielectric layer and the cap layer; and
removing the cap layer before forming the work function metal layer over the gate dielectric layer.

15. The method for forming the semiconductor device structure as claimed in claim 11, further comprising:
forming a cap layer over the gate dielectric layer before forming the first glue layer over the gate dielectric layer, wherein the first glue layer is formed over the cap layer; and
removing the cap layer after removing the gate electrode layer and the first glue layer and before forming the work function metal layer over the gate dielectric layer.

16. The method for forming the semiconductor device structure as claimed in claim 15, wherein the first glue layer is thinner than the cap layer.

17. The method for forming the semiconductor device structure as claimed in claim 11, wherein the removing of the gate electrode layer comprises:
performing a wet etching process.

18. A semiconductor device structure, comprising:
a substrate;
a gate dielectric layer over the substrate, wherein the gate dielectric layer comprises fluorine;
a work function metal layer over the gate dielectric layer;
a glue layer over the work function metal layer, wherein the glue layer is thinner than the gate dielectric layer; and
a gate electrode over the glue layer, wherein the gate electrode comprises fluorine.

19. The semiconductor device structure as claimed in claim 18, wherein the work function metal layer comprises fluorine.

20. The semiconductor device structure as claimed in claim 19, wherein a first fluorine concentration of the gate electrode is greater than a second fluorine concentration of the work function metal layer, and the second fluorine concentration is greater than a third fluorine concentration of the gate dielectric layer.
